(19) United States
(12) Patent Application Publication
(10) Pub. No.: US 2015/0192651 A1
(43) Pub. Date: Jul. 9, 2015

(54) Receiving Apparatus for Receiving a Useful Signal

(71) Applicant: Michael Wiehl, Ochsenfurt (DE)

(72) Inventor: Michael Wiehl, Ochsenfurt (DE)

(21) Appl. No.: 14/591,801

(22) Filed: Jan. 7, 2015

(30) Foreign Application Priority Data
Jan. 7, 2014 (DE) 102014200043.2

(51) Int. Cl. G01R 33/36

(52) U.S. Cl. CPC G01R 33/3621

(57) ABSTRACT

A receiving apparatus for receiving a useful signal is provided. The receiving apparatus includes a plurality N of antennas for receiving a respective carrier signal containing the useful signal, and a determination device for determining channel properties of N transmission channels before receiving the carrier signals. The receiving apparatus also includes a transmission channel for transmitting the respective carrier signal being assigned to each antenna, and a switching matrix for selecting M transmission channels from the N transmission channels based on the determined channel properties, where 1≦M<N. The switching matrix has a combination algorithm for combining the carrier signals of the M selected transmission channels. The receiving apparatus also includes a demodulation device for determining the useful signal from the received M carrier signals of the M selected and combined transmission channels.

This application claims the benefit of DE 10 2014 200 043.2, filed on Jan. 7, 2014, which is hereby incorporated by reference in its entirety.

### BACKGROUND

The present embodiments relate to a receiving apparatus of a magnetic resonance tomograph for receiving a useful signal.

A receiver is provided to transmit measurement data wirelessly in systems (e.g., magnetic resonance tomographs (MRT)) using broadband transmission methods (e.g., frequency modulation (FM), phase modulation (PM) or quaternary phase shift keying (QPSK)). Since the carriers or carrier signals may be eliminated at the receiving antenna on account of multipath effects in the radio channel, a plurality of antennas are to be installed in the MRT. The receiver also combines the carriers received at the same time and extracts the useful signals to be transmitted therefrom by demodulation.

In current MRTs, a carrier is filtered from the signal received at the antenna using a filter in a filter bank. The undesirable adjacent carriers are suppressed in this case. Each carrier is mixed into an intermediate frequency using a carrier front-end and is amplified and digitized. In the complex baseband, the carriers from different antennas may be combined in order to compensate for the carrier elimination at the receiving antennas. Algorithms such as maximum ratio combining or constant modulus algorithm may be used for this purpose.

However, an antenna front-end, a filter bank and as many carrier front-ends as carriers that are simultaneously received and processed are provided for each antenna in this case. Therefore, a total of 300 carrier front-ends are provided, for example, for 10 antennas and 30 carriers, as may occur in an MR measurement.

### SUMMARY AND DESCRIPTION

The scope of the present invention is defined solely by the appended claims and is not affected to any degree by the statements within this summary.

The present embodiments may obviate one or more of the drawbacks or limitations in the related art. For example, a receiving apparatus that makes it possible to reduce the receiving elements is provided.

Accordingly, a receiving apparatus for receiving a useful signal is provided. The receiving apparatus includes a plurality N of antennas for receiving a respective carrier signal containing the useful signal, and a determination device for determining channel properties of N transmission channels before receiving the carrier signals. The receiving apparatus also includes a transmission channel for transmitting the respective carrier signal being assigned to each antenna, and a switching matrix for selecting M transmission channels from the N transmission channels based on the determined channel properties, where 1≦M<N. The switching matrix has a combination algorithm for combining the carrier signals of the M selected transmission channels, and a demodulation device for determining the useful signal from the received M carrier signals of the M selected and combined transmission channels.

The receiving apparatus is based on the idea of determining channel properties before actually transmitting the carrier signals containing the useful signal and, based on these channel properties, selecting transmission channels that are used to determine the useful signal. In this manner, M carrier signals of the N transmitted carrier signals are used to actually determine (e.g., demodulate) the signals and therefore the useful signal.

The receiver complexity may therefore be greatly reduced. Since each carrier signal is received as many times as there are receiving antennas, the carrier signal is received more often than is actually necessary. If, for example, in the case of 10 antennas, 8 carrier signals (e.g., carriers) are only weakly received, the receiver may choose from the two good-quality carriers received and may switch through one of the two good-quality carriers using the switching matrix. This already makes it possible to dispense with 9 carrier front-ends.

In addition to assessing the transmission channels by determining the channel properties, a combination algorithm is used to combine a particular number of signals (e.g., two). A “maximum ratio combining” algorithm, for example, may be used for this purpose. This provides that, after preselecting the transmission channels based on the channel properties (e.g., the best two), the carrier signals of these selected transmission channels are combined.

In this context, a plurality of N antennas may also be understood as being N antenna positions each with at least one antenna.

According to one embodiment, the channel properties of the N transmission channels may be predicted over a particular period.

In the case of a magnetic resonance tomograph, for example, the channel properties may be predicted at least over a measurement period since the channel properties are influenced at most by the breathing of a patient in the magnetic resonance tomograph. Therefore, the channel properties of the transmission channels may be determined for a particular period before the start of the transmission of the useful signal.

According to another embodiment, the channel properties of the N transmission channels are static over a particular period.

For example, the channel properties may be considered to be static. This provides that no or virtually no changes to the channel properties and therefore to the quality of the transmitted signals may be expected over this measurement period.

According to one embodiment, the particular period is a useful signal transmission period of a system (e.g., a measurement period of a magnetic resonance tomograph).

In the case of a magnetic resonance tomograph, for example, it may be assumed that the channel properties may be predicted or are even static during a measurement period.

According to another embodiment, the combination algorithm is set up to combine the carrier signals of the at least two selected transmission channels to form a resulting signal with a greater signal-to-noise ratio.

This makes it possible to achieve the situation in which the resulting signal has a greater signal-to-noise ratio (SNR). In other words, the quality of the resulting signal is better than the quality of the carrier signals of the two selected transmission channels alone in each case. Further optimization of the signal quality may therefore be achieved.

According to another embodiment, the receiving apparatus has a plurality N of channel bundle front-ends for converting the received carrier signals into respective intermediate frequency signals.

In the channel bundle front-ends, the carrier signals may be mixed into an intermediate frequency, amplified and digitized. The channel bundle front-ends may have an amplifier, a filter and a mixer for this purpose.

According to another embodiment, the receiving apparatus has at least one filter bank for extracting a carrier signal from the intermediate frequency signals.

The at least one filter bank may have a plurality of filters. In this case, a carrier signal is filtered from the received overall signal. Such a filter bank may be used in a frequency-division multiplexing method. Other elements may also be present in other multiplexing methods.

According to another embodiment, the number of filter banks corresponds to the number of antennas.

Since one carrier signal is intended to be processed for each antenna, each filter bank is set up to filter out a corresponding carrier signal for an antenna. Therefore, a filter bank is assigned to each antenna.

According to another embodiment, the demodulation device has a plurality of carrier front-ends for digitizing the received carrier signal of the at least one selected transmission channel.

Since the carrier signals are received as analog signals, the demodulation device converts the analog signals into digital signals. A carrier front-end is provided for each selected transmission channel. Since only a subset of the entire set of transmission channels is selected, the number of carrier front-ends may therefore be reduced in comparison with conventional receivers.

According to another embodiment, each carrier front-end has an analog/digital converter.

With the aid of the analog/digital converter (AD converter), the analog signal may be digitized before forwarding and may be converted into a digital signal. Upstream of the AD converter, each carrier front-end may have a mixer and an amplifier.

According to another embodiment, the demodulation device is set up to convert the digitized carrier signal into a baseband signal.

After digitization, the carrier signal may be converted into a baseband signal. In this case, the baseband signal corresponds to the frequency range of the useful signal.

According to another embodiment, the determination device is set up to determine the channel properties before each transmission of the useful signal.

According to this embodiment, the channels to be used are selected before each transmission of the useful signal (e.g., before each MR measurement). Alternatively, for example, in the case of diversity, the higher-quality channel may be evaluated in each case during transmission. This is easily possible in the case of digital transmission. If analog transmission (e.g., phase and frequency modulation as an example of broadband transmission methods) is used, this is possible only with a large amount of effort in the complex baseband. The carriers are to be synchronized before the switching operation since otherwise data is lost. This may be avoided according to the receiving apparatus of one or more of the present embodiments by previously selecting the radio channels to be used.

According to another embodiment, each of the plurality of antennas is set up to receive part of an overall frequency range.

A plurality of antennas with varying frequency ranges may be used for each antenna position in order to jointly cover the entire frequency range to be received.

Another aspect provides a magnetic resonance tomograph having a plurality of transmitters for transmitting a useful signal, and a receiving apparatus having the above-described properties for receiving the useful signal.

The transmitters may be transmitting devices that are suitable for modulating the useful signal and transmitting the useful signal to the receiving apparatus.

Another aspect provides a method for receiving a useful signal. The method includes receiving a respective carrier signal containing the useful signal using a plurality N of antennas, and determining channel properties of N transmission channels before receiving the carrier signals. A transmission channel for transmitting the respective carrier signal is assigned to each antenna. The method also includes selecting M transmission channels from the N transmission channels based on the determined channel properties, where 1≦M<N. The method includes combining the carrier signals of the M selected transmission channels, and determining the useful signal from the received M carrier signals of the M selected and combined transmission channels.

A computer program product that causes the method explained above to be carried out on a program-controlled device is also provided.

A computer program product (e.g., a computer program device; a non-transitory computer-readable storage medium) may be provided or delivered, for example, as a storage medium (e.g., a non-transitory computer-readable storage medium such as a memory card, a USB stick, a CD-ROM, a DVD) or else in the form of a downloadable file from a server in a network. This may be effected, for example, in a wireless communication network by transmitting a corresponding file containing the computer program product or the computer program.

The embodiments and features described for the receiving apparatus accordingly apply to the method.

Further possible implementations of the invention also include not explicitly mentioned combinations of features or embodiments described above or below with respect to the exemplary embodiments. In this case, a person skilled in the art will also add individual aspects as improvements or additions to the respective basic form of the invention.

### BRIEF DESCRIPTION OF THE DRAWINGS

FIG. 1 shows a schematic view of a first exemplary embodiment of a receiving apparatus for receiving a useful signal in a magnetic resonance tomograph;

FIG. 2 shows a schematic view of a second exemplary embodiment of a receiving apparatus for receiving a useful signal in a magnetic resonance tomograph;

FIG. 3 shows a schematic view of a third exemplary embodiment of a receiving apparatus for receiving a useful signal in a magnetic resonance tomograph;

FIG. 4 shows a schematic view of a fourth exemplary embodiment of a receiving apparatus for receiving a useful signal in a magnetic resonance tomograph; and

FIG. 5 shows an exemplary embodiment of a method for receiving a useful signal in a magnetic resonance tomograph.

In the figures, same or functionally same elements have been provided with the same reference symbols unless indicated otherwise.

### DETAILED DESCRIPTION

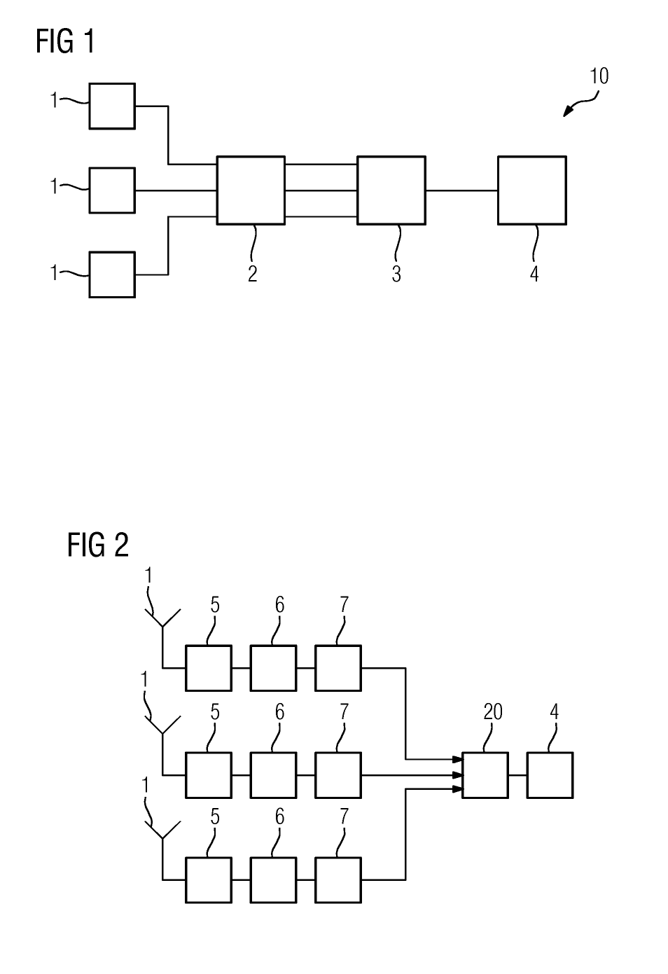

FIG. 1 shows one embodiment of a receiving apparatus 10 for receiving a useful signal (e.g., in a magnetic resonance tomograph). The useful signal may include measurement data from sensors of the magnetic resonance tomograph. The useful signal, which is modulated onto carrier signals, is transmitted between a transmitter and the receiving apparatus 10 via a radio channel as the transmission channel.

In order to receive a respective carrier signal containing the useful signal, the receiving apparatus 10 includes a plurality N of antennas 1. A determination device 2 is used to determine the channel properties of N transmission channels before receiving the carrier signals. In this case, a transmission channel for transmitting the respective carrier signal is assigned to each antenna 1.

M transmission channels are then selected from the N transmission channels based on the determined channel properties and are combined with the aid of a switching matrix 3. In this case, 1≦M<N, with the result that only a subset of the total number of transmission channels is used to actually transmit and receive the carrier signals.

A demodulation device 4 then determines the useful signal from the received M carrier signals of the M selected transmission channels.

FIG. 2 shows a second exemplary embodiment of a receiving apparatus 10. Although not shown in FIG. 2, the transmission channels are selected, as described in FIG. 1. The antennas 1 shown in FIG. 2 therefore already correspond to a subset selected based on the channel properties.

In this embodiment, each antenna 1 is connected to an antenna front-end 5. The antenna front-ends 5 process the received carrier signals before the received carrier signals are forwarded to filter banks 6. The filter banks 6 filter out the adjacent carrier signals for each antenna transmission path, with the result that only one carrier signal for each antenna 1 is processed further.

The carrier signals are converted into digital signals in the subsequent channel front-ends 7. A combination algorithm 20 is then carried out. The combination algorithm 20 combines the carrier signals such that the resulting signal has better quality (e.g., a greater signal-to-noise ratio). The signal combined in this manner is then demodulated in the demodulation device 4, which results in the transmitted useful signal.

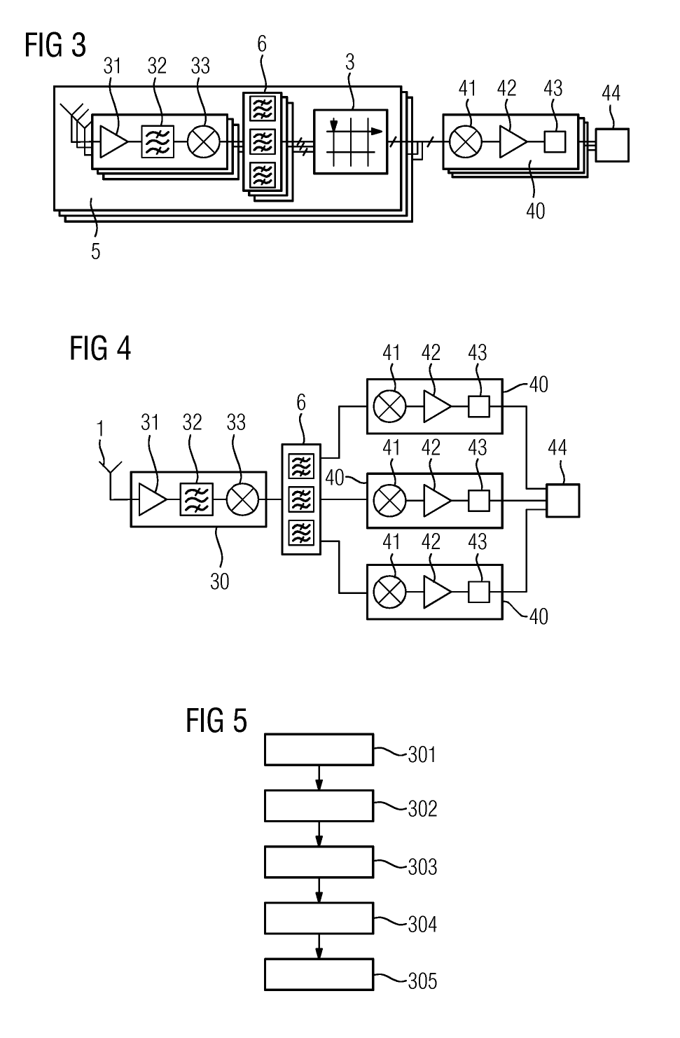

FIG. 3 shows a third embodiment of a receiving apparatus 10.

A plurality of antennas 1 with varying frequency ranges may be used for each antenna position in order to jointly cover the entire frequency range to be received. For each antenna 1, a channel bundle front-end 30 converts the received carrier signal into an intermediate frequency. Each channel bundle front-end 30 has an amplifier 31, a filter 32 and a mixer 33 for this purpose. Inside a following filter bank 6, the desired carrier is extracted from the carrier signal at the intermediate frequency. After passing through the switching matrix 3, the carrier signal is mixed into a further intermediate frequency suitable for the AD converter 43 in the carrier front-end 40 using a mixer 41 and an amplifier 42 and is digitized. The carrier signals are then combined in the complex baseband 44 in order to counteract elimination of the carrier signals in the radio or transmission channel.

As already explained, each transmission channel, between each transmitting antenna and each receiving antenna 1, may be considered to be predictable during an MR measurement since the transmission channel is either static or is influenced only by the patient's breathing. Therefore, all available radio channels may be checked before each measurement with the aid of the determination device 2, which may be combined with the switching matrix 3. Since each carrier signal is received as many times as there are receiving antennas 1, the carrier signal is received more often than is actually necessary. If, in the case of 10 antennas, 8 carrier signals are only weakly received, the receiving apparatus 10 may choose from the two good-quality carrier signals received and may switch through one of the two good-quality carrier signals using the switching matrix 3. This already makes it possible to dispense with 9 carrier front-ends 40. Therefore, for N1 carrier signals and N2, N1×N2 carrier front-ends 40 are not required, but rather only N1+N3, where N3 is the number of redundant channels.

FIG. 4 shows an exemplary embodiment of a conventional receiving apparatus without a switching matrix 3.

In this case, a carrier signal is filtered from the signal received at the antenna 1 using a filter inside the filter bank 6. The undesirable adjacent carrier signals are suppressed in this case. Each carrier signal is mixed into an intermediate frequency using a carrier front-end 40, is amplified and is digitized. In the complex baseband, the carrier signals from different antennas 1 may be combined in order to compensate for carrier elimination at the receiving antennas. An antenna front-end 30, a filter bank 6 and as many carrier front-ends 40 as carrier signals that are simultaneously received and processed are therefore provided for each antenna 1. A total of 300 carrier front-ends 40 are therefore provided for 10 antennas 1 and 30 carrier signals, as may occur in an MR measurement, for example.

The number of carrier front-ends 40 may be reduced by the receiving apparatus 10 that is described with reference to FIGS. 1, 2 and 3 and uses the switching matrix 3 and the determination device 2. This also reduces the complexity of the entire receiving apparatus 10.

FIG. 5 shows an exemplary embodiment of a method for receiving a useful signal (e.g., in a magnetic resonance tomograph).

In act 301, a respective carrier signal containing the useful signal is received using a plurality N of antennas 1.

In act 302, channel properties of N transmission channels are determined before receiving the carrier signals. In this case, a transmission channel for transmitting the respective carrier signal is assigned to each antenna 1.

In act 303, M transmission channels are selected from the N transmission channels based on the determined channel properties. In this case, 1≦M<N, with the result that only a subset M of the N transmission channels is used for the actual transmission.

Act 302 and act 303 are carried out before or at the same time as act 301.

In act 304, the carrier signals of the M selected transmission channels are combined.

In act 305, the useful signal is determined from the received M carrier signals of the M selected transmission channels.

Although the present invention was described using exemplary embodiments, the present invention may be modified in various ways.

It is to be understood that the elements and features recited in the appended claims may be combined in different ways to produce new claims that likewise fall within the scope of the present invention. Thus, whereas the dependent claims appended below depend from only a single independent or dependent claim, it is to be understood that these dependent claims can, alternatively, be made to depend in the alternative from any preceding or following claim, whether independent or dependent, and that such new combinations are to be understood as forming a part of the present specification.

While the present invention has been described above by reference to various embodiments, it should be understood that many changes and modifications can be made to the described embodiments. It is therefore intended that the foregoing description be regarded as illustrative rather than limiting, and that it be understood that all equivalents and/or combinations of embodiments are intended to be included in this description.

1. A receiving apparatus for receiving a signal, the receiving apparatus comprising:
a plurality of antennas configured to receive a respective carrier signal containing the signal;
a determination device configured to determine channel properties of transmission channels before receiving the carrier signals, a transmission channel of the transmission channels for transmitting the respective carrier signal being assigned to each antenna of the plurality of antennas;
a switching matrix configured to select a subset of transmission channels from the transmission channels based on the determined channel properties, wherein the subset of transmission channels comprises one or more but less than all of the transmission channels, the switching matrix configured to combine the carrier signals of the selected subset of transmission channels; and
a demodulation device configured to determine the signal from the received carrier signals of the selected and combined subset of transmission channels.

2. The receiving apparatus of claim 1, wherein the channel properties of the transmission channels are predictable over a particular period.

3. The receiving apparatus of claim 1, wherein the channel properties of the transmission channels are static over a particular period.

4. The receiving apparatus of claim 2, wherein the particular period is a signal transmission period of a system.

5. The receiving apparatus of claim 4, wherein the particular period is a measurement period of a magnetic resonance tomograph.

6. The receiving apparatus of claim 1, wherein the switching matrix is configured to combine the carrier signals of at least two selected transmission channels to form a resulting signal with a greater signal-to-noise ratio.

7. The receiving apparatus of claim 1, further comprising a plurality of channel bundle front-ends configured to convert the received carrier signals into respective intermediate frequency signals.

8. The receiving apparatus of claim 6, further comprising at least one filter bank configured to extract a carrier signal from the intermediate frequency signals.

9. The receiving apparatus of claim 7, wherein the number of filter banks corresponds to the number of antennas of the plurality of antennas.

10. The receiving apparatus of claim 1, wherein the demodulation device includes a plurality of carrier front-ends configured to digitize the received carrier signal of the at least one selected transmission channel.

11. The receiving apparatus of claim 10, wherein each carrier front-end of the plurality of carrier front-ends includes an analog/digital converter.

12. The receiving apparatus of claim 10, wherein the demodulation device is configured to convert the digitized carrier signal into a baseband signal.

13. The receiving apparatus of claim 1, wherein the determination device is configured to determine the channel properties before each transmission of the useful signal.

14. The receiving apparatus of claim 1, wherein each antenna of the plurality of antennas is configured to receive part of an overall frequency range.

15. A magnetic resonance tomograph comprising:
a plurality of transmitters configured to transmit a measurement signal; and
a receiving apparatus configured to receive the measurement signal, the receiving apparatus comprising:
a plurality of antennas configured to receive a respective carrier signal containing the measurement signal;
a determination device configured to determine channel properties of transmission channels before receiving the carrier signals, a transmission channel of the transmission channels for transmitting the respective carrier signal being assigned to each antenna of the plurality of antennas;
a switching matrix configured to select a subset of transmission channels from the transmission channels based on the determined channel properties, wherein the subset of transmission channels comprises less than all of the transmission channels, the switching matrix configured to combine the carrier signals of the selected subset of transmission channels; and
a demodulation device configured to determine the measurement signal from the received carrier signals of the selected and combined subset of transmission channels.

16. A method for receiving a first signal, the method comprising:
receiving a respective carrier signal containing the first signal using a plurality of antennas;
determining channel properties of transmission channels before receiving the carrier signals, a transmission channel for transmitting the respective carrier signal being assigned to each antenna of the plurality of antennas;
selecting a subset of transmission channels from the transmission channels based on the determined channel properties, wherein the subset of transmission channels comprises less than all of the transmission channels;
combining the carrier signals of the subset of the selected transmission channels; and
determining the first signal from the received carrier signals of the selected and combined subset of transmission channels.
